(19) United States
(12) Patent Application Publication
(10) Pub. No.: US 2015/0147488 A1
(43) Pub. Date: May 28, 2015

(54) PLASMA ENHANCED VAPOR PHASE DEPOSITION

(71) Applicants: SK hynix Inc., Icheon (KR); INDUSTRY-ACADEMIC COOPERATION FOUNDATION, YONSEI UNIVERSITY, Seoul (KR)

(72) Inventors: Doo Jin CHOI, Seoul (KR); Jin Hwan JEONG, Goyang (KR); Su Bin AN, Seoul (KR)

(21) Appl. No.: 14/554,964

(22) Filed: Nov. 26, 2014

(30) Foreign Application Priority Data
Nov. 26, 2013 (KR) 10-2013-0144926

(51) Int. Cl. C23C 16/50; C23C 16/455; C23C 16/458

(52) U.S. Cl. CPC C23C 16/50; C23C 16/458; C23C 16/45523; C23C 16/455; C23C 16/45565
USPC 427/569; 118/723 R

(57) ABSTRACT

A plasma enhanced vapor deposition apparatus includes a process chamber including a first space and a second space, a substrate holder provided in the first space and supporting a substrate, a plasma generating device combined to the process chamber and inducing plasma in the second space, an ion species screening member separating the first and second spaces from each other and filtering ion species to prevent the ion species from diffusing from the second space to the first space, a first gas supplier supplying a first process gas including a precursor gas into the first space, wherein the precursor gas includes atoms constituting a material layer deposited over the substrate, a second gas supplier supplying a second process gas including a reactive gas into the second space, and a gas discharger coupled to the process chamber and inducing a gas flow from the second space to the first space.

### CROSS-REFERENCES TO RELATED APPLICATION

This application claims the benefit of Korean Patent Application No. 10-2013-0144926, filed on Nov. 26, 2013, in the Korean Intellectual Property Office, the disclosure of which is incorporated herein in its entirety by reference.

### BACKGROUND

1. Field of the Invention

The present invention relates to a technique for fabricating semiconductor device, and more particularly, to a plasma enhanced vapor deposition apparatus for depositing a non-volatile data storing film, a plasma enhanced vapor deposition method, and a computer readable recording medium.

2. Description of the Related Art

Due to recent increases in demands for portable digital application devices, such as smart phones, tablet PCs, and digital cameras, the non-volatile memory market is rapidly growing. An example of programmable non-volatile memory devices is a flash memory. Since a 16 kb EEPROM was introduced in 1983, flash memories have been continuously scaled down, and 516 GB flash memories are currently available. However, as such a flash memory is scaled down to less than 45 nm, the applications of the flash memory is almost at its limit due to the deterioration of endurance (number of times that flash memory cells can be programmed) and a low programming speed not less than 100 ms.

As a non-volatile memory device for replacing the flash memory, researches are being actively made on universal memories, which are new memories featuring high integration density, low cost, and high-speed writing/reading operations and can even be applied to the domains of conventional DRAMs and SRAMs based on random accessibility and high endurance. As such universal memories, a phase change random access memory (PcRAM), a resistive random access memory (ReRAM), and a magnetic random access memory (MRAM) using variable resistors of which resistance value may be reversibly changed are being spotlighted. From among the memory devices, the PcRAM is considered to be closest to the stage of commercialization.

The PcRAM tends to be designed to have a confined structure in which a phase change material is filled in a via hole or a trench formed at an interlayer insulation layer for reducing programming current (or reset current) and preventing thermal crosstalk between neighboring cells. To form a memory cell having the confined structure, it is necessary to secure gap fill efficiency corresponding to an aspect ratio of the via hole or the trench. To meet this requirement, chemical vapor deposition, electroplating, liquid solution formation, and atomic layer deposition are suggested.

However, in such the cutting edge deposition methods, highly precisional controllability of thickness, uniformity, conformality, and low-temperature deposition are required. For an ultra large scale integrated non-volatile memory device, the atomic layer deposition is considered to be currently the most appropriate technique among the deposition methods. However, since phase change material layers are generally multicomponent metal alloys, in the atomic layer deposition, it is also demanded to resolve problems including unevenness in properties of a synthesized phase change material layer depending on selection of a precursor, energy conditions or thermodynamic conditions, to continuously improve gap fill efficiency and secure deposition speed suitable for mass production.

### SUMMARY

The present invention provides a plasma enhanced vapor deposition apparatus capable of depositing a variable resistance material layer, such as a phase change material layer, which is a non-volatile data storing layer, in a 3D structure including a via hole or a trench having a high aspect ratio, at excellent step coverage, high reliability, and high productivity.

The present invention also provides a plasma enhanced vapor deposition method having the above-stated advantages.

The present invention also provides a computer readable recording medium having recorded thereon program instructions for performing a plasma enhanced vapor deposition method having the above-stated advantages.

According to an embodiment of the present invention, there is provided a plasma enhanced vapor deposition apparatus including a process chamber comprising a first space and a second space, being in communication with each other; a substrate holder provided in the first space and configured to support a substrate; a plasma generating device combined to the process chamber and configured to induce plasma in the second space; an ion species screening member configured to separate the first and second spaces from each other and filter ion species to prevent the ion species from diffusing from the second space to the first space; a first gas supplier configured to supply a first process gas comprising a precursor gas into the first space, wherein the precursor gas includes atoms constituting a material layer deposited over the substrate; a second gas supplier configured to supply a second process gas comprising a reactive gas into the second space; and a gas discharger coupled to the process chamber and configured to induce a gas flow from the second space to the first space.

According to an embodiment of the present invention, the first process gas comprises two or more precursor gases, and the two or more precursor gases are alternately supplied into the first space in pulses at least one time. The plasma generating device may include a remote plasma source.

The remote plasma source may be coupled with an expanding portion extending from the second space of the process chamber The second gas supplier may be coupled with the expanding portion, and the second process gas may be supplied into the second space in plasma state.

In an exemplary embodiment of the present invention, the plasma enhanced vapor deposition apparatus may further include a third gas supplier coupled with the expanding portion to supply a third process gas including an inert gas suitable for discharging and maintaining the plasma. The plasma generating device may be disposed in the second space and may be capacitive-coupled with the ion species screening member. The plasma may be induced as the second process gas may be supplied between the electrode and the ion species screening member.

The plasma enhanced vapor deposition apparatus may further include a third gas supplier coupled with the remote plasma source to supply an inert gas, and the second process gas may be supplied to the downstream of the remote plasma source and may be excited by plasma of the inert gas.

In an exemplary embodiment of the present invention, the ion species screening member may include at least one selected from a plate including at least one opening, a mesh, an electrified wall, and an electron source having at least one through hole. The ion species screening member may be an electric conductor and may be grounded.

The maximum width of the opening may be from about 0.5 mm to about 5 mm, and the second process gas may be continuously supplied while the first process gas may be supplied in pulses.

The plasma generating device may maintain the plasma while the second process gas is being continuously supplied. The first process gas may include at least one selected from organo-metallics, metal halides, metal amides, metal amidinates, alkylamides, metal acetamidinates, metal silyamides, and alkyl-silyls.

In an exemplary embodiment of the present invention, when the second process gas is an oxidative process gas, the oxidative process gas may include at least one selected from oxygen (O₂) and ozone (O₃). When the second process gas is a reductive process gas, the reductive process gas may include at least one selected from hydrogen (H₂), nitrogen (N₂), ammonia (NH₃), hydrogen azide (HN₃), hydrazine (N₂H₄), nitrogen fluoride (NF₃), moisture (H₂O), and alcohols. The substrate may include a via hole or a trench pattern, and the phase change material layer may be buried in the via hole or the trench pattern.

The material layer may include a phase change material layer. The phase change material may include at least one selected from germanium (Ge), antimony (Sb), tellurium (Te), and selenium (Se), and temperature of the substrate may be in a range from the room temperature to about 350° C. while the phase change material layer is being formed.

According to other embodiment of the present invention, there is provided a plasma enhanced vapor deposition method for forming a variable resistance material layer in a process chamber including a first space and a second space communicating with each other and inducing a gas flow from the first space to the second space, the plasma enhanced vapor deposition method including providing a substrate, the substrate disposed on a substrate holder in the first space; supplying a first process gas comprising a precursor gas containing atoms constituting the variable resistance material layer into the first space in pulses; supplying a second process gas containing a reactive gas into the second space while the first process gas is supplied in pulses; maintaining plasma in the second space while the first process gas and the second process gas are supplied. Ion species are filtered from the second process gas in a plasma state so that the ion species are prevented from spreading from the second space to the first space, and the variable resistance material layer is formed over the substrate by transporting the first process gas and neutral radicals of the reactive gas delivered from the second space over the substrate.

According to another embodiment of the present invention, there is provided a computer readable recording medium having program instructions to be executed on a process of a system for forming a variable resistance material layer and the program instructions may be executed by the processor for the system to perform the operations of the fore-mentioned plasma enhanced vapor deposition method.

### BRIEF DESCRIPTION OF THE DRAWINGS

Hereinafter, embodiments of the present invention will be described in greater detail with reference to the accompanying drawings.

FIGS. 1A and 1B are perspective sectional views illustrating memory cells of phase change memory devices according to embodiments of the present invention;

FIGS. 2A and 2B show plasma enhanced vapor deposition apparatuses according to embodiments of the present invention, and FIG. 2C shows a direct plasma enhanced vapor deposition apparatus according to a comparative embodiment;

FIGS. 3A through 3C are perspective views of ion species screening members according to embodiments of the present invention;

FIG. 4 is a flowchart showing a plasma enhanced vapor deposition method according to an embodiment of the present invention, and FIG. 5 is a timing diagram of the plasma enhanced vapor deposition method;

FIGS. 6A and 6B are scanning microscopic images showing cross-sections of phase change materials deposited when plasma power was 70 W and temperatures of substrates were 150° C. and 200° C., and FIG. 6C is a scanning microscopic image showing a cross-section of a phase change material deposited according to the comparative embodiment;

FIG. 7A is a scanning electron microscopic image showing a cross-section of a phase change material layer deposited when plasma power was 100 W and temperature of a substrate was 150° C., according to an embodiment of the present invention, and FIG. 7B is a scanning electron microscopic image showing a cross-section of a phase change material deposited according to the comparative embodiment;

FIG. 8 is a graph showing a result of a X-ray diffraction analysis of deposited SbTe material layers with respect to changes of temperature of a substrate;

FIG. 9A is a graph showing a result of measuring as-deposited sheet resistances of SbTe phase change material layers deposited at various substrate temperatures according to embodiments of the present invention, and FIG. 9B is a graph showing a result of measuring sheet resistances of SbTe phase change material layers according to changes of an injection ratio between pulses of a Sb precursor gas and a Te precursor gas; and

FIG. 10 is a graph showing a current-voltage (I-V) characteristics of a memory cell including a SbTe phase change material layer deposited according to an embodiment of the present invention.

### DETAILED DESCRIPTION OF THE INVENTION

The present invention will now be described more fully with reference to the accompanying drawings, in which exemplary embodiments of the invention are shown.

The invention may, however, be embodied in many different forms and should not be construed as being limited to the embodiments set forth herein; rather these embodiments are provided so that this disclosure will be thorough and complete, and will fully convey the concept of the invention to one of ordinary skill in the art.

The same reference numerals denote the same elements in the drawings. As used herein, the term “and/or” includes any and all combinations of one or more of the associated listed items.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” used herein specify the presence of stated features, integers, steps, operations, members, components, and/or groups thereof, but do not preclude the presence or addition of one or more other features, integers, steps, operations, members, components, and/or groups thereof.

It will be understood that when a layer is referred to as being “formed on,” another layer, it can be directly formed on the other layer or intervening layers may be present therebetween. Likewise, when a material is referred to as being adjacent to another material, intervening materials may be present therebetween. In contrast, when a layer or material is referred to as being “directly” formed on, to another layer or material or as being “directly” adjacent to or contacting another layer or material, there are no intervening materials or layers therebetween.

The relative terms including “below,” “above,” “upper,” “lower,” “horizontal,” and “vertical” may be used to describe a relationship between an element, a layer, or a region and another element, another layer, or another region as shown in the drawings. It should be understood that the terms are not limited to the orientations shown in the drawings.

The present invention will now be described more fully with reference to the accompanying drawings, in which exemplary embodiments of the invention are shown. In the drawings, for example, sizes and shapes of members may be exaggerated for clarity and convenience of explanation. Accordingly, the shapes may be modified actually. Accordingly, it should not be construed as being limited to specific shapes of regions. Furthermore, the same reference numerals denote the same elements in the drawings.

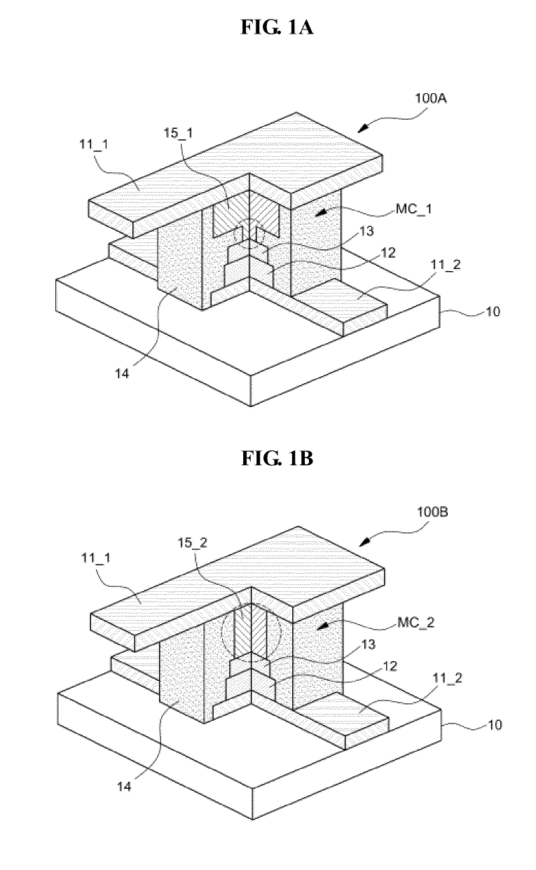

FIGS. 1A and 1B are perspective sectional views illustrating memory cells MC_{—}1 and MC_{—}2 of phase change memory devices 100A and 100B according to embodiments of the present invention. FIGS. 1A and 1B only illustrate portions of cell array areas, and conventional arts may be referred to in relation to circuit elements constituting peripheral areas adjacent to the cell array areas, e.g., high-voltage transistors, low-voltage transistors, and wirings for electric connections therebetween.

Referring to FIGS. 1A and 1B, the memory cells MC_{—}1 and MC_{—}2 formed on a substrate 10 are provided between wirings 11_1 and 11_2 which extend in different directions and cross each other, e.g., bit lines and word lines. The memory cells MC_{—}1 and MC_{—}2 may be electrically connected to a selecting device 12. The selecting device 12 may be a current steering device or a switching device, such as a diode and a transistor.

An electrode 13, which functions as a heater, may be formed on the selecting device 12. The memory cells MC_{—}1 and MC_{—}2 and other memory cells adjacent thereto (not shown) are electrically separated by an interlayer insulation layer 14. In the interlayer insulation layer 14, as illustrated in FIGS. 1A and 1B, via holes which expose at least partial surfaces of the electrode 13, may be formed. As indicated by dotted lines, the via holes may be filled with phase change material layers 15_1 and 15_2.

In the memory cells MC_{—}1 and MC_{—}2, the phase change material layers 15_1 and 15_2 are buried in via holes or trench patterns, contact the electrode 13 therebelow such that the phase change material layers 15_1 and 15_2 and electrode 13 may have the minimum contact area, and heat from the contact area may be trapped in the via holes or trench patterns, thereby constituting a confined structure with reduced current consumption and thermal interference. FIG. 1A shows a cell structure in which a portion (the area indicated with the dotted line) of a phase change material layer 15 is buried, whereas FIG. 1B shows a cell structure in which the entire phase change material layer 15 (as indicated with the dotted line) is buried.

The phase change material layers 15_1 and 15_2 may contain a chalcogen compound. For example, the chalcogen compound may be a solid solution located on the pseudo-binary line between GeTe and Sb₂Te₃ in a ternary system phase equilibrium diagram of Ge—Sb—Te. For example, the phase change material may be Ge₂Sb₂Te₅, In_{0.5}Sb₂Te_{2.9}, Sb₂Te₃, Ge_{7.5}Sb_{92.5}, GeSb₂Te₃, GeSb₂Te₄, BiSe, GeTeAs, GeSnTe, SeSnTe, GaSeTe, GeTeSnAu, SeSb₂, InSe, GeTe, BiSeSb, PdTeGeSn, InSeTiCo, InSbTe, In₃SbTe₂, GeTeSb₂, GeTe₃Sb, GeSbTePd, or AgInSbTe. However, the above-stated embodiments are merely examples, and the phase change material layer may be formed of a compound of binary, ternary, or higher system. The system may include at least one of germanium (Ge), antimony (Sb), tellurium (Te), and selenium (Se) and have different resistances in amorphous state and crystalline state, e.g., CuSe. Furthermore, the above-stated material may be further doped with an impurity atom, e.g., non-metal atoms like B, C, N, and P.

Although the above-stated embodiments relate to a via hole, the electrode 13 may also be exposed via a trench pattern, and the phase change material layers 15_1 and 15_2 may be partially or entirely buried in the trench pattern. The phase change material layer is fabricated in a plasma enhanced vapor deposition process described below, where an ultra large scale integrated memory cell having a size smaller than the critical dimension of a photolithography process may be formed by forming the phase change material layer in a via hole or a trench pattern and performing chemical-mechanical polishing (CMP) until the top surface of the surrounding interlayer insulation layer 14 is exposed. Although the above-stated structure relates to a phase change memory device, the present invention may also be applied to a resistive memory or a magnetic memory having a cross-point structure.

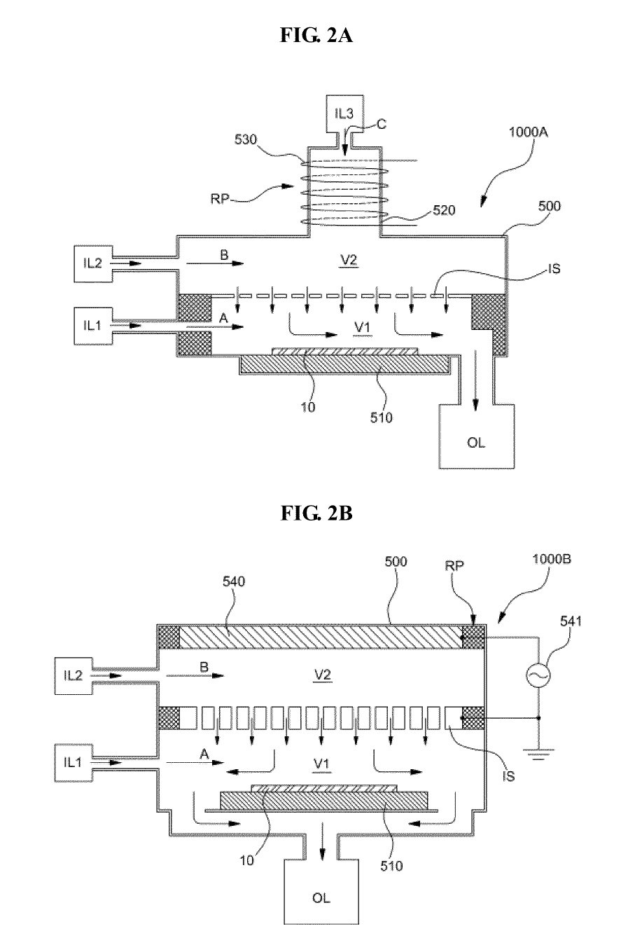

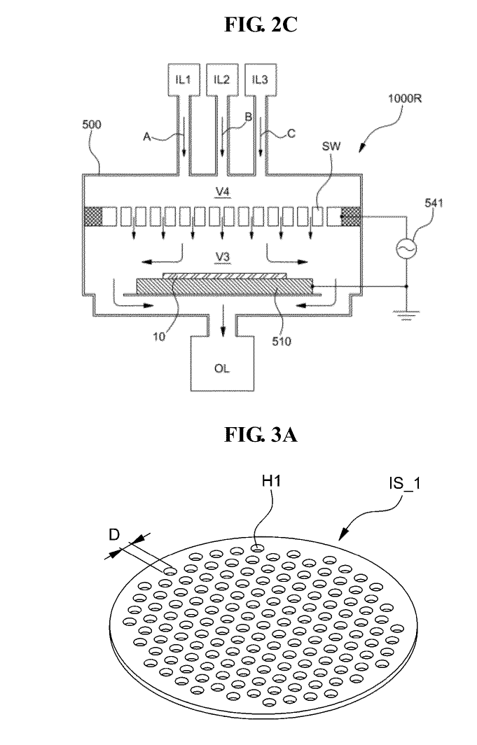

FIGS. 2A and 2B show plasma enhanced vapor deposition apparatuses 1000A and 1000B according to embodiments of the present invention, and FIG. 2C shows a direct plasma enhanced vapor deposition apparatus 1000R according to a comparative example.

Referring to FIG. 2A, a process chamber 500 includes a first space V1 and a second space V2, which can be communicated with gas. The first space V1 and the second space V2 may be separated from each other by an ion species screening member IS. Detailed descriptions of the ion species screening member IS will be given below. A substrate holder 510 for supporting the substrate 10 is provided in the first space V1. A variable resistance material layer, e.g., a phase change material layer, is to be formed on the substrate 10. A plurality of substrates may be loaded on the substrate holder 510.

A first gas supply unit IL1 for supplying a first process gas (indicated with the arrow A) including a precursor gas containing composition elements of the phase change material layer is coupled to the first space V1. The first gas supply unit IL1 may include a container, for example, a canister, for accommodating source materials for generating a precursor gas, a pipeline for delivering the precursor gas to the first space V1 of the process chamber 500, and a valve system for controlling flow of the precursor gas. A carrier gas may be used for delivering the precursor gas, wherein the carrier gas may flow via the canister and the pipeline and then be introduced into the first space V1 together with the precursor gas.

If the phase change material layer is formed of an alloy including 2 or more metals, the precursor gas may include two or more precursor gases. In such a case, the first gas supply unit IL1 may be multiplied for controlling flows of the respective precursor gases. For example, a canister or a bubbler, a pipeline, and a valve system may be allocated to each precursor gas, and the first gas supply unit IL1 including a plurality of gas supply lines for alternate pulse supply of the precursor gases may be provided.

A second process gas (indicated with the arrow B) including a reactive gas used for oxidization or redox of the phase change material layer, a precursor gas or intermediate layer generated during formation of the phase change material layer is provided into the second space V2 of the process chamber 500. To provide the second process gas, a second gas supply unit IL2 may be coupled to the second space V2. Similar to the first gas supply unit ILL the second gas supply unit IL2 may include a suitable pipeline and valve system. In case of using a gaseous source for the reactive gas, members like a canister may be omitted. According to an embodiment of the present invention, the reactive gas may be supplied into the second space V2 together with an inert gas. The inert gas may include at least one selected from helium, neon, argon, xenon, and krypton.

A plasma generating device for inducing plasma in the second space V2 of the process chamber 500 may be coupled to the second space V2. The plasma generating device may be provided inside or outside the process chamber 500 defining the second space V2. Basically, the plasma generating device may locally ignite and maintain plasma in the second space V2. According to embodiments of the present invention, the plasma generating device may be an electrode (not shown) that is provided inside the second space V2 of the process chamber 500 and is combined with a direct current or alternated current power supply. In another example, the plasma generating device may be an electromagnetic field induction coil or a magnet (not shown) provided outside the process chamber 500 to restrict plasma within the process chamber 500. The above-stated devices are merely examples, and other plasma sources well known in the art, such as a microwave generating device suitable for discharging and maintaining plasma, may be utilized.

According to embodiments of the present invention, the plasma generating device may be a remote plasma generating device RP, as illustrated in FIG. 2A. The remote plasma generating device RP may include a remote plasma source coupled to an expanding portion 520 expanding from the second space V2. In this embodiment, plasma is locally and densely generated in the expanding portion 520. In this case, the second space V2 may be located under the expanding portion 520. The remote plasma source may be an electromagnetic field induction coil, a magnet, or a microwave generating device. FIG. 2A shows an electromagnetic field induction coil 530 that is used as the remote plasma source. However, embodiments are not limited thereto.

According to embodiments of the present invention, the second gas supply unit IL2 may be coupled to the expanding portion 520. In this case, the second process gas may be ionized and thus its state may be converted into a plasma state in the expanding portion 520 by the remote plasma source, i.e., the electromagnetic field induction coil 530. The ionized second process gate may be delivered to the second space V2.

Alternatively, as illustrated in FIG. 2A, the second gas supply unit IL2 may be directly coupled to the second space V2, and an additional third gas supply unit IL3 may be coupled to the expanding portion 520. A third process gas (indicated with the arrow C) suitable for discharging and maintaining plasma, e.g., an inert gas, may be supplied into the expanding portion 520 via the third gas supply unit IL3. The inert gas in a plasma state may spread or diffuse into the second space V2 and excite the second process gas supplied through the second gas supply unit IL2 coupled to the second space V2.

According to another embodiment of the present invention, an additional gas supply unit for supplying a purge gas into the first space V1, the second space V2, or the expanding portion 520 may be provided. The purge gas may be provided during a period between pulses of the precursor gas to remove a residual gas or an impurity gas in the process chamber 500.

To induce a gas flow from the second space V2 to the first space V1 of the process chamber 500, the plasma enhanced vapor deposition apparatus 1000A may include a discharging unit OL. As illustrated in FIG. 2A, the discharging unit OL may be directly coupled to the first space V1 to induce the gas flow from the second space V2 to the first space V1. An outlet of the discharging unit OL is not necessarily disposed at an end portion of the process chamber 500, and may be disposed at a center-bottom portion of the process chamber 500 as shown in FIG. 2B.

As known in the art, the discharging unit OL may include a low-pressure vacuum pump and a valve system for controlling pressure of the process chamber 500. Via the discharging unit OL, unreacted materials or by-products formed during vapor deposition of the phase change material layer may be purged.

The first space V1 and the second space V2 may be separated from each other via the ion species screening member IS. The ion species screening member IS is disposed between the first space V1 and the second space V2 to selectively deliver neutral species, such as radicals of the second process gas in a plasma state formed in the second space V2, into the first space V1, while the ion species screening member IS blocks ion species of the second process gas in the plasma state to be delivered into the first space V1. The ion species screening member IS may be configured to include an opening region for communicating the first space V1 with the second space V2 to transmit neutral species and filtering positive ion species with high energy by forming a sheath contacting plasma in the second space V2 or by providing electrons for reducing the positive ion species. For example, the ion species screening member IS may be a plate, a mesh, an electrified wall, or an electron source including a through hole as the opening region, or may have a configuration in which features of the above-stated elements are combined. FIG. 2A shows a mesh-type ion species screening member IS.

A plasma enhanced vapor deposition apparatus may be configured such that the first process gas A flows horizontally with respect to a main surface of the substrate 10, as illustrated in FIG. 2A. Furthermore, to this end, an inlet of the first gas supply unit IL1 and an outlet of the discharging unit OL may be arranged at two opposite ends around the substrate 10. However, it is merely an example, a suitable showerhead or a mixing member may be provided in the first space V1, such that the first process gas A is mixed with neutral species transmitted through the ion species screening member IS and the mixed gas is supplied to the main surface of the substrate 10 with a uniform vertical flow. Similarly, the second process gas B is also not limited to configurations regarding horizontal flow and may be supplied in the second space V2 with a vertical flow or a complex flow by using a nozzle or a mixing member.

Referring to FIG. 2B, the remote plasma source RP according to another embodiment of the present invention may include a capacitive coupled plasma source. The capacitive coupled plasma source may be provided in the process chamber 500 and locally form plasma in the second space V2. The capacitive coupled plasma source may be provided with an electrode 540 for generating plasma and continuously supplying energy and the ion species screening member IS as an opposite electrode to the electrode 540.

The electrode 540 may have an exposed surface in the second space V2 and be capacitive-coupled with the ion species screening member IS. According to an embodiment of the present invention, the electrode 540 may be connected to an RF power 541, while the ion species screening member IS may be grounded. Although not shown, a matching network for matching impedance may be coupled between the electrode 540 and the RF power 541.

The second process gas B including a reactive gas may be introduced into the second space V2 by the second gas supply unit IL2 and be converted into a plasma state. If the ion species screening member IS is a plate-like component including via holes, the ion species screening member IS may function as a showerhead for uniformly delivering neutral species of the second process gas to the first space V1. However, the above-stated showerhead is different from a general showerhead, in that a blocking region and an opening region of the ion species screening member IS are appropriately adjusted and grounded for filtering ion species. As long as not being contradictory, regarding the other component illustrated in FIG. 2B, which are the first gas supply unit IL1 and the discharging unit OL, the description given above with reference to FIG. 2A may be referred to.

According to an embodiment of the present invention, the first process gas A including a precursor gas and the second process gas B including a reactive gas for oxidation and reduction are respectively supplied into the separate spaces V1 and V2 of the process chamber 500 divided by the ion species screening member IS, wherein plasma may be dominantly or locally formed only in the second space V2 in the process chamber 500. Therefore, the first process gas supplied into the first space V1 is not directly discharged, nor directly reacts with the second process gas in the plasma state in the second space V2. As a result, according to an embodiment of the present invention, a vapor deposition apparatus, which is capable of independently performing handling properties of a first process gas and process parameter control for controlling the first process gas in the first space V1, and handling properties of reactive radicals and process parameter control for controlling the reactive radicals in the second space V2, may be provided.

As only neutral species, such as reactive radicals, among the second process gas in a plasma state are delivered from the second space V2 onto the substrate 10 in the first space V1 via the ion species screening member IS, the precursor gas and/or a surface of a phase change material layer formed on the substrate 10 may react with the reactive radicals. According to an embodiment of the present invention, due to a designed reaction between the reactive radicals and a precursor gas and/or a phase change material layer with high-energy ion species excluded, deposition may be performed regardless of ion species, and energy and density of the reactive radicals may be selectively controlled regardless of ion species. Therefore, an effective sticking coefficient of a precursor gas with respect to a substrate, which affects step coverage, may be manipulated directly by controlling the reactive radicals. Furthermore, according to an embodiment of the present invention, even if power for plasma increases to increase deposition speed, ion species do not affect vapor deposition, and thus step coverage and deposition speed of a phase change material layer can be improved. As a result, a variable resistance memory device, preferably, a phase change memory device may be fabricated with high productivity and high reliability.

In the embodiment illustrated in FIG. 2B, it is illustrated that the first process gas A is introduced in a horizontal direction. However, embodiments are not limited thereto. By appropriately arranging a mixing member, which mixes neutral species delivered through the ion species screening member IS and the first process gas A, and the discharging unit OL, the mixed gas may flow in a vertical direction with respect to the main surface of the substrate 10 inside the first space V1.

The direct plasma enhanced vapor deposition apparatus 1000R according to the comparative example shown in FIG. 2C is compared with a plasma enhanced vapor deposition apparatus according to the present invention. The direct plasma enhanced vapor deposition apparatus 1000R includes a showerhead SW and a substrate holder (or an electrode) 510. The showerhead SW and the electrode 510 may be capacitive-coupled with each other and form plasma in a reactive space V3. A plurality of gas supply units IL1, IL2, and IL3 for introducing a precursor gas, a carrier gas, and a reactive gas, respectively, into the process chamber 500 may be coupled to the process chamber over the showerhead SW. The direct plasma enhanced vapor deposition apparatus 1000R according to the comparative example is differentiated from the plasma enhanced vapor deposition apparatuses 1000A and 1000B according to embodiments of the present invention in which a precursor gas and a reactive gas are changed into a plasma state in different spaces. In the direct plasma enhanced vapor deposition apparatus 1000R, a precursor gas A and a reactive gas B are mixed in a space V4, plasma is simultaneously formed in the space V4, and vapor deposition of a phase change material layer on the substrate 10 is performed in another space V3.

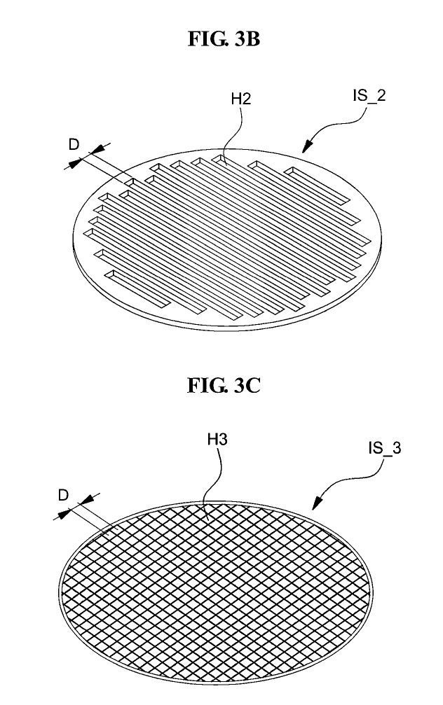

FIGS. 3A through 3C are perspective views of ion species screening members IS_{—}1, IS-2, and IS_{—}3 according to embodiments of the present invention.

Referring to FIGS. 3A and 3B, the ion species screening members IS_{—}1 and IS_{—}2 may be plate-type members having at least one or more openings H1 and H2. The openings H1 and H2 may have a hole shape and a slit shape, respectively. Although the circular opening H1 is illustrated in FIG. 3A, the opening H1 may be an elliptical hole or a polygonal hole such as a rectangular hole and a hexagonal hole, embodiments are not limited thereto. Furthermore, the slit-shape opening H2 may be formed in any of various shapes suitable for sheath formation.

A width D of the openings H1 and H2 may be determined, such that the openings H1 and H2 contact plasma in a second space (V2 of FIG. 2A) of a process chamber, form a plasma sheath, and function as a barrier against charged species. For example, the width D of the openings H1 and H2 may be smaller than or equal to twice of a width W of a plasma sheath obtained nearby the openings H1 and H2 under plasma enhanced vapor deposition conditions (in other words, D=2 W). It is known that the width W of the plasma sheath is comparable to the Debye length λ_{D} shown below in Equation 1, or smaller than or equal to ten times of λ_{D}.

$${λ}_{D} = {( \frac{{ε}_{0} κ {T}_{e}}{{n}_{0} {e}^{2}} )}^{1 / 2} \qquad [ Equation 1 ]$$

Here, ε₀ denotes permittivity in a vacuum state, n₀ denotes a plasma density (cm⁻³), e denotes a charge amount of electrons, and Tₑ denotes electron temperature eV. According to Equation 1 above, when power applied to plasma decreases, the electron temperature increases and the plasma density decreases. Thus a thickness of a plasma sheath may increase. On the contrary, if power applied to plasma increases, the electron temperature decreases and the plasma density increases. Thus the thickness of the plasma sheath may decrease. Under vapor deposition conditions according to an embodiment of the present invention, the maximum width D of the openings H1 and H2 in consideration of the plasma sheath may be from about 0.5 mm to about 5 mm.

If the width D is too small, reactive species may be deposited on a surface of the ion species screening member, thereby causing a side effect like pollution. As an another approach, the width D of the openings H1 and H2 may be set, and a plasma density and electron temperature may be modulated by controlling power to plasma and pressure for controlling a width of a plasma sheath, thereby obtaining an ion species filtering effect. While ion species cannot pass through the openings H1 and H2 of the ion species screening member due to the plasma sheath, radicals, which are neutral species, are delivered to the first space V1 of the process chamber 500 via the openings H1 and H2 regardless of the plasma sheath.

FIG. 3C shows a mesh-type ion species screening member IS_{—}3. The mesh may be formed of a porous metal plate or crossing metal wires. Size D of each hole of the mesh may be appropriately selected to be smaller than or equal to twice of size S of a plasma sheath as described above. Shape of each hole of the mesh may be any polygon, such as a triangle, a rectangle, or a hexagon. However, embodiments are not limited thereto.

The ion species screening members may be formed of a ceramic or a polymer electric insulator such as Teflon. Alternatively, the ion species screening members may be formed of a conductor, such as a stainless steel or a conductive polymer. An ion species screening member formed of a conductor may be grounded. However, embodiments are not limited thereto. Furthermore, a charged wall unit or an electron source may be used as an ion species screening member. The charged wall unit and the electron source may reduce ion species, thereby removing ionic properties or increasing activated neutral species.

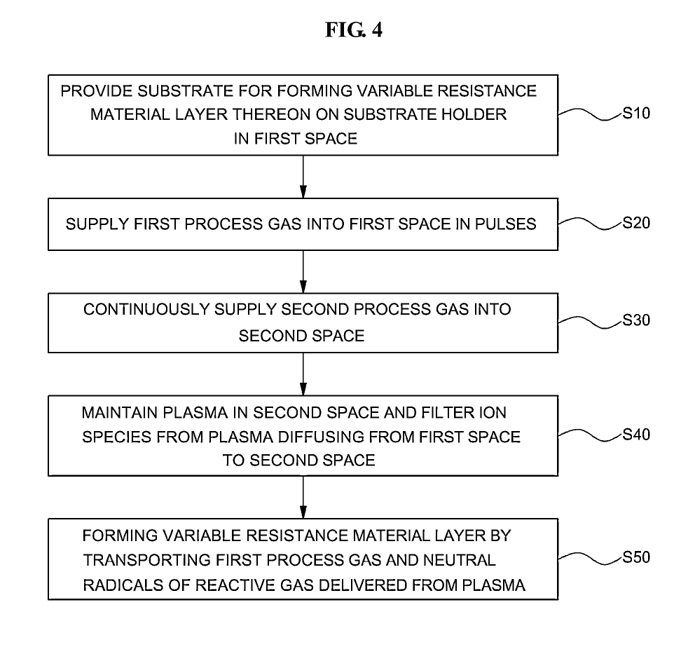

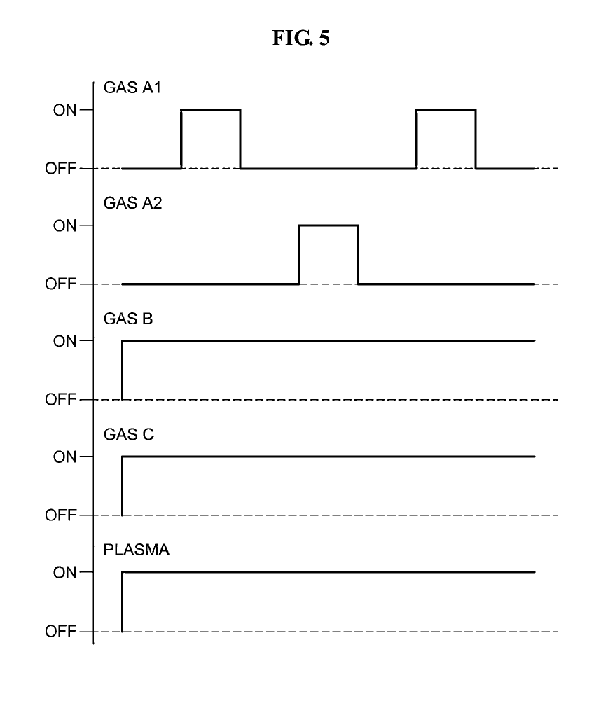

FIG. 4 is a flowchart showing a plasma enhanced vapor deposition method according to an embodiment of the present invention, and FIG. 5 is a timing diagram of the plasma enhanced vapor deposition method. For vapor deposition of a variable resistance material layer, the plasma enhanced vapor deposition apparatus 1000A or 1000B having the first space V1 and the second space V2 as described above with reference to FIGS. 2A and 2B may be utilized.

Referring to FIG. 4, a substrate, on which a variable resistance material layer, preferably, a phase change material layer is to be formed, is provided on a substrate holder in a first space of the plasma enhanced vapor deposition apparatus (step S10). A first process gas including a precursor gas of atoms constituting the variable resistance material layer may be supplied into the first space in pulses (step S20). The precursor gas may be one or more selected from organo-metallics (e.g., alkyl compounds including atoms constituting the variable resistance material layer), metal halides, metal amides, metal amidinates, alkylamides, metal acetamidinates, metal silyamides, and alkyl-silyls. However, the above-stated precursor compounds are merely examples, and embodiments are not limited thereto. In other embodiments, precursor gases used for atomic layer deposition, molecular beam epitaxy, or chemical vapor deposition may be used.

If the variable resistance material layer is formed of an alloy including two or more metal atoms, the precursor gas may include a plurality of precursor gases respectively including the metal atoms. For example, if a variable resistance material layer is a phase change material layer of a SbTe-based alloy, two types of precursor gases respectively including antimony (Sb) and tellurium (Te) may be supplied in pulses. In this case, as shown in FIG. 5, pulses of a Sb precursor gas A1 and pulses of a Te precursor gas A2 may be alternately supplied at least once. A suitable purging process of providing a purge gas to the first space may be performed between the pulses.

In the conventional ALD process, pulsed supply of each precursor gas may be designed, such that at least a corresponding precursor fulfills self-limiting absorption required during the process. However, in embodiments of the present invention, a radical-assisted vapor deposition can be available, and thus, in comparison to the conventional ALD process, the self-limiting adsorption is not necessarily required in the embodiments of the present invention. Therefore, it can be focused to increase of a deposition rate of a variable resistance material layer on inner walls of via holes or trenches during the deposition process, since it is not necessary to induce saturation step for a self-limiting process of a corresponding precursor gas on a surface of a substrate. Furthermore, since the present invention does not necessarily depend on the self-limiting process, it is not necessary to limit selection of precursors to combinations of precursor gases which have availability for chemical reactions including ligand exchange or condensation, thereby offering a wide choice of precursors.

A composition ratio of a variable resistance material layer may be controlled by adjusting widths of pulses for supplying corresponding precursor gases or a pulse supply ratio of precursor gases. If the phase change material layer is a ternary alloy like GeSbTe, three precursor gases respectively including the respective atoms are required, and the precursor gases are alternately and repeatedly supplied in pulses at least one time. The precursor gases may be delivered to the first space V1 of a process chamber alone, or be carried thereto by a carrier gas.

While a first process gas including precursor gases is delivered to the first space V1, a second process gas including a reactive gas for oxidizing or reducing a material layer, such as a phase change material layer or an intermediate layer being deposited, may be continuously supplied into a second space (step S30). The reactive gas may render suitable radicals being able to be combined with the precursor gases, e.g., hydrogen radicals, to be absorbed on a surface of the material layer, such that the precursors are easily absorbed to the substrate.

The oxidative second process gas may be oxygen (O₂) or ozone (O₃), whereas the reductive second process gas may be hydrogen (H₂), nitrogen (N₂), ammonia (NH₃), hydrogen azide (HN₃), hydrazine (N₂H₄), or nitrogen fluoride (NF₃). However, the above-stated gases are merely examples, and embodiments are not limited thereto. In other embodiments, steam (H₂O) or an alcohol, such as methanol, ethanol, or prophanol, may be used.

For example, during deposition of a SbTe-based alloy, while a Sb precursor gas A1 and a Te precursor gas A2 are alternately supplied into the first space V1 in pulses, a reactive gas B, such as H₂ or NH₃, is continuously supplied into the second space V2. Furthermore, an inert gas contributing discharge and maintenance of plasma, such as helium, neon, argon, xenon, or krypton, may be supplied into the second space V2 together with the reactive gas B.

While the first process gases A1 and A2 and the second process gas B are supplied, a plasma state of the second process gas B is maintained in the second space V2. While the plasma state of the second process gas B is maintained in the second space V2, ion species are filtered (step S40). The ion species may be filtered by using an ion species screening member as described above.

A reaction formula below is for describing interaction between a precursor gas and a reductive reactive gas according to an embodiment of the present invention.

Second Space V2: H₂→H*+H* (by plasma)

First Space V1: MX_{Y}+H*→M (on substrate)+XH (gas) [Reaction Formula]

Although hydrogen H₂, which is the reductive reactive gas in the second space V2, is ionized or excited into a plasma state, species delivered to the first space V1 are hydrogen radicals H*, which are neutral species, due to filtering of ion species.

While the plasma state of the second process gas B is maintained in the second space V2, the hydrogen radicals H*, which are neutral species, flow onto a surface of a substrate or a surface of a material layer and react with the precursor gas, such that a variable resistance material layer M is deposited on the substrate with excellent step coverage (step S50). In some embodiments, the plasma may be generated by a remote plasma source as described above. In this case, an inert gas C may be continuously supplied to the remote plasma source, e.g., the expanding portion 520 described above with reference to FIG. 2A, for discharging the plasma and purging the first process gas supplied in pulses.

Molecular stability of a precursor gas for forming the variable resistance material layer may be improved via so-called chelate effect by adding a metal atom to a ligand. It is difficult to remove such chelated ligands only with a reductive reactive gas, such as hydrogen or ammonia. However, according to an embodiment of the present invention, since a reactive gas is excited into a plasma state, chelated ligands may be easily removed, and thus concentrations of impurities that may be trapped in a variable resistance material layer may be removed or reduced. Such a radical-assisted deposition enables vapor deposition without depending on a typical self-limiting process for atomic layer deposition, thereby offering a wide choice of precursor gases.

If ion species having high kinetic energy are involved in a deposition process during formation of a phase change material layer, a precursor gas may be excessively activated even before a deposition and thus over-deposited on surfaces of via holes or a trench pattern, and thus overhang of a phase change material is formed around an upper portion of the via holes or the trench pattern. As a result, gap-fill or step coverage of the phase change material layer may be deteriorated. However, according to embodiments of the present invention, involvement of ion species during formation of a phase change material layer is blocked. Instead, as highly-excited radicals of a reactive gas are only involved in the formation of the phase change material layer, decomposition of precursor gases is accelerated and an absorption rate of the decomposed precursor gases on a surface of a substrate is slightly reduced. Therefore, due to increase of the number of precursor molecules introduced toward the bottom of the via holes or the trench pattern, problems like overhang may be substantially prevented such that gap fill or step coverage properties may be improved. The effects are valid even if power for plasma increases, and thus fast deposition, fine thin-film quality, and low-temperature process may be simultaneously secured according to embodiments of the present invention.

Hereinafter, embodiments of the present invention will be described in closer details with reference to an experiment. The experiment described below is merely an example, and embodiments are not limited thereto.

[Experiment]

As a comparative example of the plasma enhanced vapor deposition apparatus according to the embodiment of the present invention shown in FIG. 2A, a SbTe-based phase change material layer was deposited by using the direct plasma enhanced vapor deposition apparatus shown in FIG. 2C. A deposition thickness was about 50 nm.

A substrate was a silicon substrate, and a bottom electrode was a titanium nitride layer. A trench pattern was formed on an insulation layer of a silicon nitride layer via a photolithography process. Tris-dimethylamino antimony (TDMASb) was used as a Sb precursor gas, whereas Di-tertiarybutyl telluride (Te(t-Bu)₂) was used as a Te precursor gas. Argon was used as a carrier gas for precursor gases, and flux of each of the precursor gases was 50 sccm.

H₂ gas and NH₃ gas were used as reactive gases and were supplied into a second space of a process chamber at the flux of 10 sccm. Duration of a pulse of each of the precursor gases was 2 seconds, and reactive gases were continuously supplied while plasma discharge was continuously maintained. The plasma was RF plasma having an excitation frequency of 13.56 MHz, RF powers were 70 W and 100 W, and pressure inside the process chamber was 3 Torr. Although temperature of a substrate was in a range from about 100° C. to about 300° C., embodiments are not limited thereto, and temperature of the substrate may be in a range from the room temperature to about 350° C.

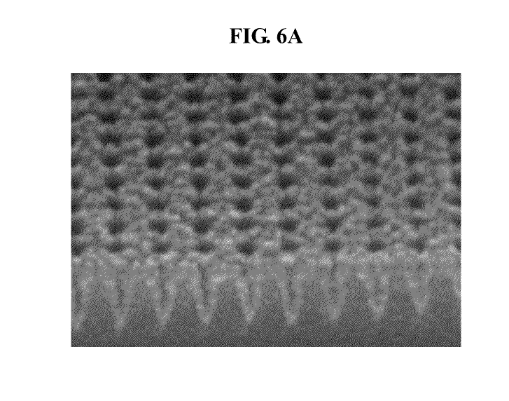

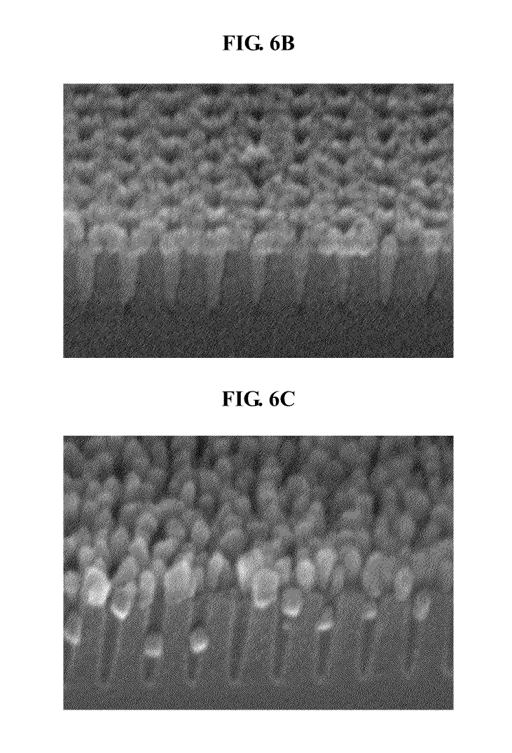

FIGS. 6A and 6B are scanning microscopic images showing cross-sections of phase change materials deposited when plasma power was 70 W and temperatures of substrates were 150° C. and 200° C., and FIG. 6C is a scanning microscopic image showing a cross-section of a phase change material deposited according to the comparative example.

Referring to FIG. 6A, a SbTe material layer was deposited on an inner sidewall of a trench pattern to a uniform thickness at 150° C. It seems that the trench pattern was not completely filled due to slow deposition of the SbTe material layer. Here, thickness of the SbTe material layer was 27.17 nm, and deposition speed was 0.479 nm/min (pulse duration: 2 s, purge duration: 15 s). However, since the SbTe material layer was deposited inside the trench pattern as an ultra-thin film having a uniform thickness, it is expected that a trench pattern will be completely filled if the trench pattern is ultra-fine.

Referring to FIG. 6B, a trench pattern was completely filled with a SbTe material layer without a void at 200° C. Uniformity of the SbTe material layer deposited on an upper region of the trench pattern was satisfactory. Such a surface morphology proves that the SbTe material layer was deposited by gradually filling the interior of the trench pattern. Here, thickness of the SbTe material layer was 61.13 nm and deposition speed was 1.079 nm/min (pulse duration: 2 s, purge duration: 15 s).

Referring to FIG. 6C, unlike in the embodiments of the present invention, in the direct plasma enhanced vapor deposition apparatus, a SbTe material layer could not fill a trench pattern, and overhangs are formed around openings of the trench pattern, and thus the trench pattern was blocked. In this case, thickness of the SbTe material layer was 88.3 nm and deposition speed was 1.558 nm/min (pulse duration: 2 s, purge duration: 15 s). The poor step coverage is exhibited, because, as both precursor gases and reactive gases were changed into a plasma state in single plasma space and ion species are involved in deposition of a phase change material layer formed on a substrate, the SbTe material layer was formed at a high deposition speed without sufficient step coverage.

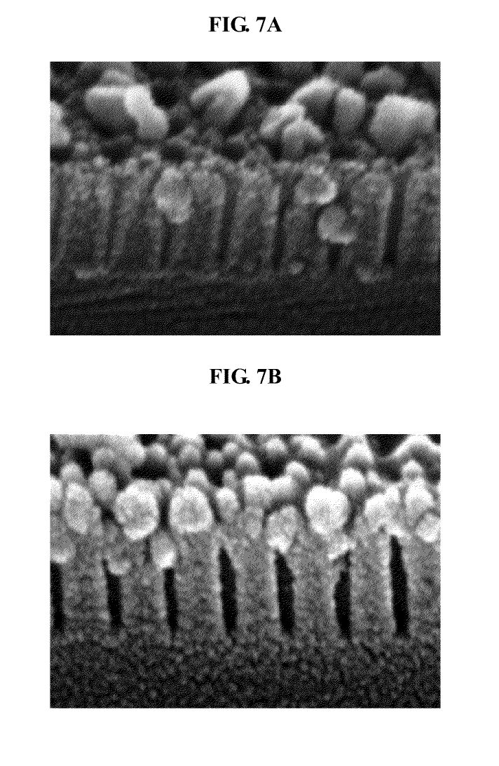

FIG. 7A is a scanning microscopic image showing a cross-section of a phase change material layer deposited when plasma power was 100 W and temperature of a substrate was 150° C., according to an embodiment of the present invention, FIG. 7B is a scanning microscopic image showing a cross-section of a phase change material deposited according to the comparative example.

Referring to FIG. 7A, compared to the experiments shown in FIGS. 6A and 6B, plasma power was increased from 70 W to 100 W. However, a SbTe material layer was still deposited on an inner sidewall of a trench pattern to a uniform thickness. It seems that step coverage was maintained because a blocking effect by a plasma sheath is not susceptible to plasma power. Therefore, according to embodiments of the present invention, a phase change material layer having excellent step coverage may be vapor-deposited even if RF power is changed within a broad range for improving deposition speed.

Referring to FIG. 7B, according to the comparative example, as plasma power was increased to 100 W, a SbTe material layer failed to completely fill a trench pattern and overhangs were formed around openings of the trench pattern, as in the case where plasma power was 70 W, the trench pattern is completely blocked by the overhanging phase change material layer. It is noted that the deterioration of step coverage is further accelerated as a deposition rate and energy of ion species further increase due to the increase of the plasma power.

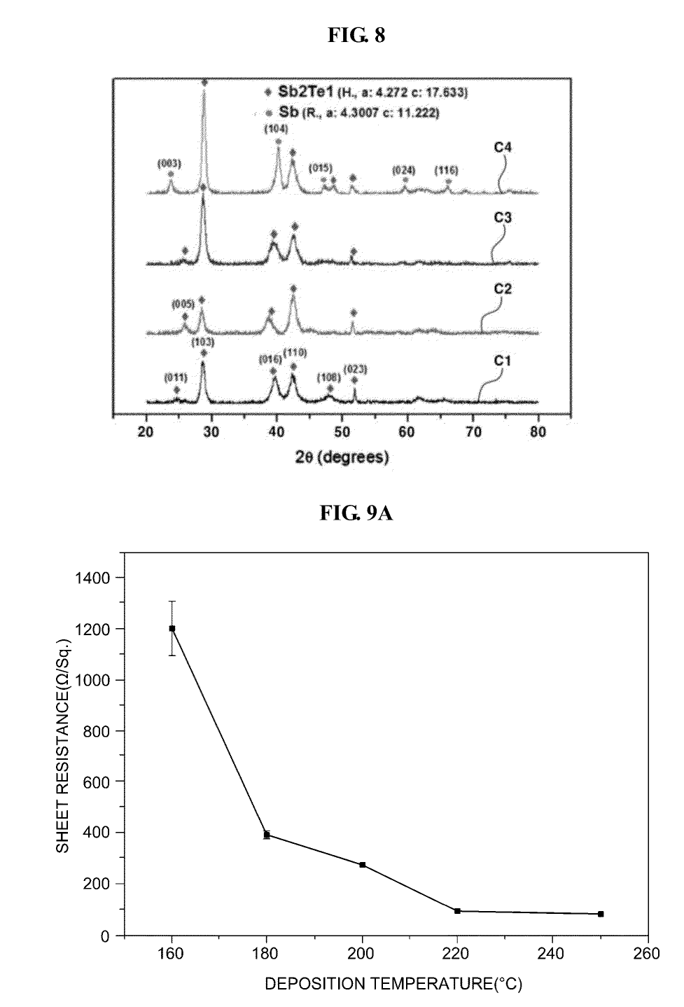

FIG. 8 is a graph showing a result of an X-ray diffraction analysis of deposited SbTe material layers with respect to changes of temperature of a substrate. Curves C1, C2, C3, and C4 indicate examples in which temperature of the substrate was 180° C., 200° C., 220° C., and 250° C., respectively. The X-ray diffraction analysis was performed in a glancing mode at 0.5° by using the Ultima IV manufactured by RIGAKU corporate.

Referring to FIG. 8, the XRD peak dominant throughout the entire temperatures was based on a hexagonal Sb₂Te₁ phase of which lattice constants a and c were 4.272 Å and 17.633 Å, respectively. Intensities of major peaks by planes (103) and (110) decreased as a deposition temperature decreased. However, it is noted that a Sb₂Te₁ phase change material layer deposited even at 180° C. had crystallinity. The reason thereof is related to low crystallization temperature of a SbTe-based phase change material layer around 150° C. As temperature of a substrate increased, Sb peak of a rhombohedral monocrystalline of which lattice constant a was 4.3007 Å and lattice constant c was 11.222 Å appeared. Based on the result, it is noted that Sb deposition is more preferred than Te deposition at a high temperature, thereby causing excessive Sb content in a SbTe phase change material layer and leading to Sb monocrystalline phase. It is generally known that it is advantageous to form a phase change material layer in an amorphous state for filling gaps of a trench pattern during atomic layer deposition or chemical vapor deposition. However, according to embodiments of the present invention, a vapor deposition process may provide excellent step coverage even in a crystalline phase of a phase change material.

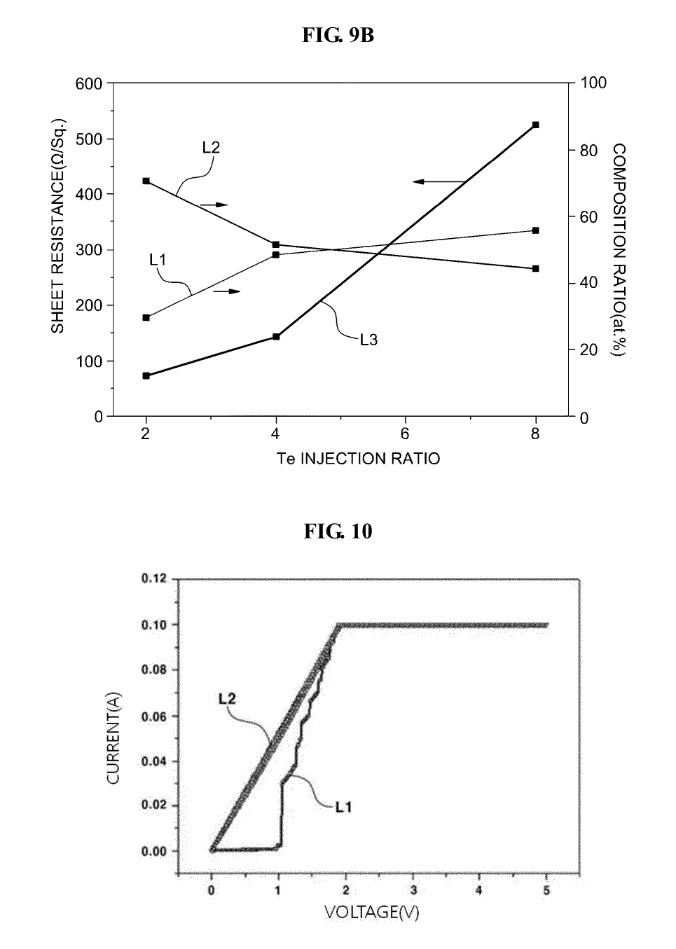

FIG. 9A is a graph showing a result of measuring as-deposited sheet resistances of SbTe phase change material layers deposited at various substrate temperatures according to embodiments of the present invention, and FIG. 9B is a graph showing a result of measuring sheet resistances of SbTe phase change material layers according to changes of an injection ratio between pulses of a Sb precursor gas and a Te precursor gas. The sheet resistances were measured by using the model CMT-SR 200N, which is a 4-point probe device.

Referring to FIG. 9A, as temperature of a substrate increased, sheet resistance decreased. Sheet resistance of a phase change material deposited at 160° C. was 1199.75Ω, which is about 15 times of sheet resistance of a phase change material deposited at 250° C. The result conforms to the change of crystallinity described above with reference to FIG. 8 and shows that the deposited SbTe phase change material layer may have binary resistances applicable to an actual device.

In FIG. 9B, a phase change material was deposited at 200° C. A curve L1 indicates composition ratio of Te in the phase change material layer, a curve L2 indicates composition ratio of Sb in the phase change material layer, and a curve L3 indicates a sheet resistance measured when the deposited phase change material is completely crystallized by thermal treatment at 300° C. for 20 minutes (that is, set state). The composition ratios of the phase change material layer were measured from a phase change material layer, which is deposited by adjusting an injection ratio between pulses of precursor gases, via a field emission scanning electron microscopy-energy dispersive X-ray spectroscopy (FESEM-EDS) by using JEM-7001F manufactured by JEOL, and a result of the measurement is shown on the right axis of the graph. Composition ratios of the phase change material layer were Sb_{70.52}Te_{29.48}, Sb_{51.62}Te_{49.38}, and Sb_{44.12}Te_{55.88} when injection ratios between Sb and Te were 1:2, 1:4, and 1:8, respectively.

Sheet resistances of the phase change material layers at the set state increase as injection ratio of Te increases, that is, composition ratio of Te increases. In terms of a PCRAM operation, since Joule heating efficiency may be improved as sheet resistance at the set state increases, increasing an injection ratio of Te increases sheet resistance, and thus the overall injection ratio between a Sb precursor gas and a Te precursor gas may be greater than 1:1 and may preferably be in a range from about 1:2 to about 1:8.

FIG. 10 is a graph showing current-voltage (1-V) characteristics of a memory cell including a SbTe phase change material layer deposited according to an embodiment of the present invention. The phase change material layer was a crystalline layer, in which Sb and Te were formed at an injection ratio of 1:2 and at 200° C., and had a thickness of 50 nm. A top electrode and a bottom electrode were TiN layers. The I-V characteristics were measured by using a semiconductor parameter analyzer (B1500A) manufactured by Agilent, where the I-V characteristics were measured by sweeping a voltage from 0 V to 5 V under 100 mA current compliance.

In FIG. 10, a curve L1 indicates a result of first sweep measurement, and a curve L2 indicates a result of second sweep measurement. Based on the results, it is determined that the phase change material layer has an electric switching feature, where a threshold voltage for the electric switching is 1.05 V. Although not shown, as an injection ratio between a Te precursor gas and a Sb precursor gas increased in the order of 1:2, 1:4, and 1:8, the threshold voltage decreased in the order of 1.05 V, 0.56 V, and 0.33 V, respectively. An electric resistance at the set state obtained by the second sweep measurement increased as the injection ratio of pulses of the Te precursor. In consideration of the result shown in FIG. 9B, it seems that the decrease of the threshold voltage is related to increased Joule heating efficiency due to high resistivity of a Te-rich SbTe phase change material layer.

The plasma enhanced vapor deposition method according to the above embodiments may be automated by combining the plasma enhanced vapor deposition apparatus according to the embodiments shown in FIGS. 2A and 2B with a controller and a communication control system. The controller includes a microprocessor, a memory, and a digital I/O port not only for delivering and activating input signals to gas supply units and plasma generating devices of the plasma enhanced vapor deposition apparatus, but also for generating sufficient control voltages for monitoring output signals from the plasma enhanced vapor deposition apparatus system. Furthermore, the controller may be combined with a process chamber, a heating member of a substrate holder, and a power supply of a plasma source and exchange data with the same.

A program stored in the memory is used for controlling each of components to implement the plasma enhanced vapor deposition apparatus and the plasma enhanced vapor deposition method according to embodiments of the present invention based on stored process recipes. An example of the controller may be a UNIX-based workstation, a general-purpose computer, or a digital signal processing (DSP) system. However, the present invention is not limited thereto. According to embodiments of the present invention, the controller may be locally arranged with respect to a plasma enhanced vapor deposition apparatus according to the present invention or may be arranged at a remote location for controlling the plasma enhanced vapor deposition apparatus via an internet or an intranet.

Although the above-stated embodiments relate to a phase change memory device employing a phase change material layer, the above-stated embodiments may also be applied to other semiconductor devices employing binary or ternary metal alloys requiring high step coverage. For example, the above-stated embodiments may be applied to other non-volatile resistive memory devices, such as a resistive random access memory (ReRAM) or a magnetic random access memory (MRAM), employing materials having different resistances reversibly switched between a low-resistance state and a high-resistance state similarly as a phase change material. Examples of the variable resistance materials include Perovskite oxides, such as SrTiO₃, SrZrO₃, and Nb:SrTiO₃, or transition metal oxides, such as TiOₓ, NiO, TaOₓ, HfOₓ, AlOₓ, ZrOₓ, CuOₓ, NbOₓ, TaOₓ, GaOₓ, GdOₓ, MnOₓ, PrCaMnO, and ZnONIOₓ. In the Perovskite oxides and the transition metal oxides, oxygen atoms may be included in the variable resistance materials by applying an oxidative reactive gas thereto.

According to embodiments of the present invention, in a plasma enhanced vapor deposition, a first process gas including a precursor gas is supplied into a first space of a process chamber, a reactive gas for oxidizing or reducing a variable resistance material layer to be deposited, the precursor gas or intermediated layer is supplied separately into a second space of the process chamber, plasma is induced in the second space, and process parameters are independently controlled in the first space and the second space, thereby optimizing reactions occurring in the respective spaces. Furthermore, while process parameters are being independently controlled, ion species can be filtered such that only neutral reactive radicals having optimal energy and exited in the second space are delivered to the first space. Therefore, overhangs of a variable resistance material layer based on over-deposition due to ion species can be suppressed, and thus a variable resistance material layer featuring excellent gap filling property and excellent productivity due to high deposition rate may be formed in a via hole or a trench pattern.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A plasma enhanced vapor deposition apparatus comprising:
a process chamber comprising a first space and a second space, which are in communication with each other;
a substrate holder provided in the first space and configured to support a substrate;
a plasma generating device combined to the process chamber and configured to induce plasma in the second space;
an ion species screening member configured to separate the first and second spaces from each other and filter ion species to prevent the ion species from diffusing from the second space to the first space;
a first gas supplier configured to supply a first process gas comprising a precursor gas into the first space, wherein the precursor gas includes atoms constituting a material layer deposited over the substrate;
a second gas supplier configured to supply a second process gas comprising a reactive gas into the second space; and
a gas discharger coupled to the process chamber and configured to induce a gas flow from the second space to the first space.

2. The plasma enhanced vapor deposition apparatus of claim 1, wherein the first process gas comprises two or more precursor gases, and
the two or more precursor gases are alternately supplied into the first space in pulses at least one time.

3. The plasma enhanced vapor deposition apparatus of claim 1, wherein the plasma generating device comprises a remote plasma source.

4. The plasma enhanced vapor deposition apparatus of claim 3, wherein the remote plasma source is coupled with an expanding portion extending from the second space of the process chamber.

5. The plasma enhanced vapor deposition apparatus of claim 4, wherein the second gas supplier is coupled with the expanding portion, and the second process gas is supplied into the second space in a plasma state.

6. The plasma enhanced vapor deposition apparatus of claim 4, further comprising a third gas supplier coupled with the expanding portion to supply a third process gas comprising an inert gas suitable for discharging and maintaining plasma generated in the expanding portion.

7. The plasma enhanced vapor deposition apparatus of claim 1, wherein the plasma generating device is disposed in the second space and includes an electrode capacitive-coupled with the ion species screening member, and
wherein the plasma is induced while the second process gas is supplied into the second space between the electrode and the ion species screening member.

8. The plasma enhanced vapor deposition apparatus of claim 3, further comprising a third gas supplier coupled with the remote plasma source and configured to supply an inert gas,
wherein the second process gas is supplied into a space under the remote plasma source and is excited by plasma generated using the inert gas.

9. The plasma enhanced vapor deposition apparatus of claim 1, wherein the ion species screening member comprises at least one selected from a plate having at least one opening, a mesh, an electrified wall, and an electron source having at least one through hole.

10. The plasma enhanced vapor deposition apparatus of claim 1, wherein the ion species screening member includes an electric conductor that is grounded.

11. The plasma enhanced vapor deposition apparatus of claim 9, wherein the maximum width of the at least one opening is in a range from about 0.5 mm to about 5 mm.

12. The plasma enhanced vapor deposition apparatus of claim 1, wherein the second process gas is continuously supplied while the first process gas is supplied in pulses.

13. The plasma enhanced vapor deposition apparatus of claim 12, wherein the plasma generating device maintains the plasma while the second process gas is continuously supplied.

14. The plasma enhanced vapor deposition apparatus of claim 1, wherein the first process gas comprises at least one selected from organo-metallics, metal halides, metal amides, metal amidinates, alkylamides, metal acetamidinates, metal silyamides, and alkyl-silyls.

15. The plasma enhanced vapor deposition apparatus of claim 1, wherein, when the second process gas is an oxidative process gas, the oxidative process gas comprises at least one selected from oxygen (O₂) and ozone (O₃), and
wherein, when the second process gas is a reductive process gas, the reductive process gas comprises at least one selected from hydrogen (H₂), nitrogen (N₂), ammonia (NH₃), hydrogen azide (HN₃), hydrazine (N₂H₄), nitrogen fluoride (NF₃), moisture (H₂O), and alcohols.

16. The plasma enhanced vapor deposition apparatus of claim 1, wherein the material layer comprises a phase change material layer,
wherein the substrate comprises a layer disposed thereon, the layer including a via hole or a trench pattern, and
wherein the phase change material layer is buried in the via hole or the trench pattern.

17. The plasma enhanced vapor deposition apparatus of claim 16, wherein the phase change material comprises at least one selected from germanium (Ge), antimony (Sb), tellurium (Te), and selenium (Se).

18. The plasma enhanced vapor deposition apparatus of claim 16, wherein temperature of the substrate is in a range from room temperature to about 350° C. while the phase change material layer is formed.

19. A plasma enhanced vapor deposition method for forming a variable resistance material layer in a process chamber including a first space and a second space communicating with each other and inducing a gas flow from the second space to the first space, the plasma enhanced vapor deposition method comprising:
providing a substrate, the substrate disposed on a substrate holder in the first space;
supplying a first process gas comprising a precursor gas containing atoms constituting the variable resistance material layer into the first space in pulses;
supplying a second process gas containing a reactive gas into the second space while the first process gas is supplied in pulses; and
maintaining plasma in the second space while the first process gas and the second process gas are supplied,
wherein ion species are filtered from the second process gas in a plasma state so that the ion species are prevented from spreading from the second space to the first space, and
wherein the variable resistance material layer is formed over the substrate by transporting the first process gas and neutral radicals of the reactive gas delivered from the second space over the substrate.

20. The plasma enhanced vapor deposition method of claim 19, wherein the filtering of the ion species is performed using an ion species screening member including at least one selected from a plate comprising at least one opening, a mesh, a charged wall, or an electron source, the ion species screening member being disposed between the first space and the second space.

21. The plasma enhanced vapor deposition method of claim 19, wherein the substrate is heated to a temperature from room temperature to about 350° C.

22. The plasma enhanced vapor deposition method of claim 19, wherein the variable resistance material layer comprises a phase change material layer,
wherein the substrate comprises a layer formed thereon, the layer including a via hole or a trench pattern, and
wherein the phase change material layer is buried in the via hole or the trench pattern.

23. The plasma enhanced vapor deposition method of claim 19, wherein the plasma is generated by a plasma generating device combined with the second space.

24. The plasma enhanced vapor deposition method of claim 23, wherein the plasma generating device comprises a remote plasma source coupled with an expanding portion extending from the second space of the process chamber, and
wherein the second process gas is supplied into the second space in a plasma state via the expanding portion.

25. The plasma enhanced vapor deposition method of claim 24, wherein the second process gas and an inert gas for generating and maintaining the plasma are supplied together through the expanding portion.

26. The plasma enhanced vapor deposition method of claim 23, wherein the plasma generating device comprises a remote plasma source coupled with an expanding portion extending from the second space of the process chamber, and
wherein the second process gas is supplied into a space under the remote plasma source.

27. The plasma enhanced vapor deposition method of claim 23, wherein the plasma generating device comprises an electrode connected to a power supply and a showerhead facing the electrode and being grounded, the electrode and the showerhead being capacitive-coupled to each other, and
wherein the plasma is induced as the second process gas is supplied into the second space between the electrode and the showerhead.

28. The plasma enhanced vapor deposition method of claim 27, where the second process gas and an inert gas for generating and maintaining the plasma are supplied together.

29. The plasma enhanced vapor deposition method of claim 19, wherein the first process gas comprises at least one selected from organo-metallics, metal halides, metal amides, metal amidinates, alkylamides, metal acetamidinates, metal silyamides, and alkyl-silyls.

30. The plasma enhanced vapor deposition method of claim 19, wherein the first process gas comprises two or more precursor gases, and
wherein the two or more precursor gases are alternately supplied in pulses at least one time.

31. The plasma enhanced vapor deposition method of claim 19, wherein when the second process gas comprises an oxidative process gas, the oxidative process gas comprises at least one of oxygen (O₂) and ozone (O₃), and
wherein when the second process gas comprises a reductive process gas, the reductive process gas comprises at least one of hydrogen (H₂), nitrogen (N₂), ammonia (NH₃), hydrogen azide (HN₃), hydrazine (N₂H₄), nitrogen fluoride (NF₃), moisture (H₂O), and alcohols.

32. The plasma enhanced vapor deposition method of claim 19, wherein the variable resistance material layer is formed by performing a self-limited process.
